(19) United States
(12) Patent Application Publication
(10) Pub. No.: US 2007/0024182 A1
(43) Pub. Date: Feb. 1, 2007

(54) Flat panel display apparatus

(76) Inventors: Keun-Soo Lee, Suwon-si (KR); Tae-Hyung Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/493,129

(22) Filed: Jul. 26, 2006

(30) Foreign Application Priority Data
Jul. 30, 2005 (KR) 10-2005-0070055

(51) Int. Cl. H01J 1/62; H01J 63/04

(52) U.S. Cl. 313/500

(57) ABSTRACT

Provided is a flat panel display device and a method for making the display device that can prevent misalignment of each of the pixels or sub-pixels of a display unit during a manufacturing process. The flat panel display device includes a substrate, a display array unit formed on the substrate, and at least one mark or trace of such a mark formed outside of the display unit. The array includes a plurality of pixels. The plurality of pixels has a layer of a material. The mark has reference for referencing in determining whether a position on a deposition mask relative to the reference means is within a predetermined tolerance limit. The deposition mask is for use in depositing the material to form the layer

### CROSS-REFERENCE TO RELATED PATENT APPLICATION

This application claims the benefit of Korean Patent Application No. 10-2005-0070055, filed on Jul. 30, 2005, in the Korean Intellectual Property Office, the disclosure of which is incorporated herein by reference in its entirety.

### BACKGROUND OF THE INVENTION

1. Field of the Invention

The present invention relates to a flat panel display device, and more particularly, to a flat panel display device made by a manufacturing process that can prevent misalignment of each pixel or sub-pixel of the display.

2. Description of the Related Art

Organic light emitting display (OLED) devices are emissive display devices that have a large viewing angle, high contrast, and rapid response time. Thus, they are considered to be next generation display devices.

A typical organic light emitting device includes a light emitting layer interposed between two electrodes facing each other. The device may further include one or more of, for example, a hole injection layer (HIL), a hole transport layer (HTL), a light emitting layer, an electron transport layer (ETL), and an electron injection layer (EIL). These layers may be thin films formed of organic materials.

The manufacturing process of an organic light emitting device involves various deposition processes. For example, the organic thin films can be formed on a substrate by a deposition method. The electrodes interposing the organic thin films can also be formed by a deposition method. Various other components of an organic light emitting device, including thin film transistors and their contacts and electrodes can also be formed by deposition processes.

To form organic or non-organic elements using the deposition methods, one or more masks are used to selectively deposit these materials only on the desired locations of the substrate and to form a pattern of the materials. A mask is a sheet patterned with a number of openings. The mask is mounted on a surface, on which the organic film or the metal film is deposited. Accordingly, the organic film or the metal film having a desired pattern is deposited only on the portions of the surface exposed through the openings formed on the mask.

To form the patterned deposition of the materials with a high precision, the mask needs to be tightly contacted with the surface of the substrate on which the deposition is performed. Often times, however, the central portion or other portions of the mask may not be tightly contacted with the substrate due to various reasons, including its self-weight in case the mask is placed under the substrate. This results in misalignment of the deposition and hence the deposited materials on the substrate. The larger the size of the mask, the greater the misalignment or the misaligned area can be.

FIG. 1 illustrates a mask frame assembly to use in mass production of display arrays. The mask frame assembly includes a mask 10, which is a metallic foil 11 with a plurality of unit masks 12, each of which has a number of openings to expose surfaces on which the deposition can be simultaneously performed. Each unit mask 12 corresponds to an array of organic light emitting diode to produce a single organic light emitting display device. The deposition using this mask 10 will produce a plurality of display arrays on a large substrate, which is cut into pieces to produce a plurality of organic light emitting display devices, each having a single array. The mask 10 is fixed on a frame 20 with tension to reduce the possibility that the mask 10 does not tightly contact the substrate.

Since the mask 10 is relatively large, the problem of misalignment of the deposition can be significant. Further, when the mask 10 is fixed on the frame 20, the problem of loose contact can be severer even though a tension is uniformly applied to the mask 10. Particularly, the large metal thin film mask 10 must be welded on the frame 20 so that the width or length of openings 12a formed in the unit mask 12 can be kept within a designed tolerance limit. When tension is applied in each direction to prevent sagging of the mask 10, it becomes impossible to keep the width or length of the openings 12a within the designed tolerance limit since pitches of the openings 12a of each of the unit masks 12 can be deformed. Particularly, when the openings 12a of the unit mask 12 in a particular region of the metal thin film 11 are deformed, the deformation force is transmitted to all openings 12a of adjacent unit masks 12. Therefore, the openings 12a of the unit masks 12 move relative to the substrate on which a material is deposited, and the deformation exceeds the tolerance limit of a designed pattern. The deformation is particularly serious in the direction perpendicular to the length direction of the openings 12a of the unit mask 12.

When the openings 12a of each of the unit masks 12 are deformed, the each of unit electrode patterns formed on the substrate and each of the unit masks 12 can be misaligned and the misalignment of accumulation of pitches (hereinafter, the total pitch) can be large. Accordingly, red, green, and blue organic thin films may not be formed at correct positions in the unit electrode patterns over the substrate. The pitch and total pitch of the unit masks 12 formed on a large metal thin film 11 can be controlled in a very limited portion of the mask 10. Therefore, there is a limit to enlarge the size of the mask 10.

When the original mask 10 is fixed on the frame 20 by applying a tension at each side thereof, as depicted in FIG. 2, two side supporting bars 21 of the frame 20 can be inwardly curved and upper and lower supporting bars 22 of the frame 20 can be outwardly curved. Also, as depicted in FIG. 3, the two side supporting bars 21 can be outwardly curved, and the upper and lower supporting bars 22 of the frame 20 can be inwardly curved. That is, the frame 20 can be distorted due to the magnitude of the tension applied to the frame 20, and accordingly, the problem of changing the total pitch can occur.

### SUMMARY OF CERTAIN INVENTIVE ASPECTS

One aspect of the present invention provides a flat panel display device that minimizes misalignment of each pixel or sub-pixel of a display unit during a manufacturing process.

Another aspect of the invention provides a display device, which may comprise a substrate comprising a first area and a second area outside the first area; a display array formed over the first area of the substrate, the array comprising a plurality of pixels, the plurality of pixels comprising a layer of a deposited material; and reference means or a trace of such means for referencing in determining whether a deformation of a deposition mask for depositing the layer is within predetermined deformation tolerance limit, the means or trace being formed over the second area of the substrate.

In the foregoing device, the reference means may provide a reference point to determine whether a distance between a position on the deposition mask and the reference point is within a predetermine distance tolerance limit. The reference means or the trace may be buried under a structure. Alternatively, the means or the trace may be exposed. The means may have a rectangular shape. The reference means may comprise a plurality of substantially parallel stripes.

Still in the foregoing device, the display array may comprise a structure made of an electrically conductive material, and the means comprises the same electrically conductive material. The structure may be selected from the group consisting of a source electrode, a drain electrode and a gate electrode of a transistor, the structure may have an elevation from a surface of the substrate, and the reference means may have an elevation from the surface of the substrate substantially the same as the elevation of the structure. The structure may be selected from the group consisting of a source electrode, a drain electrode and a gate electrode of a transistor, and wherein the reference means may be located on the same layer as the structure.

Further in the forgoing device, the display array may comprise a plurality of edges formed between the array and the substrate, and the means may be arranged along at least one of the edges. Two or more means may be arranged along at lease two of the edges of the display array. The plurality of pixels may comprise an organic light emitting diode. The means may be arranged along at least one of edges of the first area. Two or more means may be arranged along at lease two of the edges of the first area.

Another aspect of the present invention provides a method, which may comprises: providing a substrate comprising at least one mark on a predetermined position; placing a deposition mask over the substrate, the deposition mask comprising a plurality of openings, through which a plurality of portions of the substrate are exposed; and determining whether deformation of the deposition mask is within a predetermined deformation tolerance limit using the at least one mark. Determining may comprise determining whether a position on the deposition mask relative to the at least one mark is within at least one predetermine tolerance limit. Determining may comprise measuring a distance between the at least one mark and a position on the mask and comparing the measured distance with a predetermined value.

In the foregoing method, the method may further comprise replacing the deposition mask with another deposition mask, if the deformation of the deposition mask is out of the predetermined deformation tolerance limit. The deposition mask may comprise a plurality of patterns of the openings, and each pattern may be separated from one or more neighboring patterns by a non-patterned area.

Still in the foregoing method, the method may further comprises selectively depositing a material on the plurality of portions exposed through the openings of the deposition mask, thereby forming a plurality of patterns of the deposited material over the substrate, and each pattern of the deposited material is separated from one or more neighboring patterns by a non-patterned area. The method may further comprise cutting the substrate into two or more pieces along a line passing the non-patterned area.

Further in the foregoing method, providing the substrate may comprise forming the at least one mark on the substrate, and the at least one mark is formed simultaneously with one or more components of the display device formed on the substrate. The method may further comprise removing the mark from the substrate.

Still another aspect of the invention provides a flat panel display device produced by the foregoing method.

According to further aspect of the present invention, a flat panel display device comprises a substrate; a display array unit formed on the substrate; and at least one mark formed outside of the display array unit. The mark may be opaque or formed of a reflective material. The mark may have a rectangular shape or a shape of a plurality of stripes. The mark may be formed of a conductive material. In the foregoing device, the flat panel display device may further comprise a thin film transistor having a source electrode, a drain electrode, and a gate electrode, and the mark may be disposed on the same layer as at least one of the source electrode, the drain electrode, and the gate electrode. The flat panel display device may further comprise a thin film transistor having a source electrode, a drain electrode, and a gate electrode, wherein the mark may be located on the same layer as at least one of the source electrode, the drain electrode, and the gate electrode, and may be formed of the same material for forming at least one of the source electrode, the drain electrode, and the gate electrode.

Still in the foregoing device, the display array unit may include one mask. The display array unit may include a plurality of masks which are formed along at least one side of the display array unit. The display array unit may include a plurality of masks which are formed along both sides of the display array unit. The display array unit may comprise an organic light emitting diode.

### BRIEF DESCRIPTION OF THE DRAWINGS

The above and other features and advantages of the present invention will become more apparent from various embodiments thereof which are described with reference to the attached drawings.

FIG. 1 is an exploded perspective view of a conventional mask frame assembly for selectively depositing a thin film;

FIGS. 2 and 3 are plan views of conventional mask frame assemblies;

FIG. 4 is a plan view of an uncut panel for manufacturing a plurality of flat panel display devices according to an embodiment of the present invention;

FIG. 5 is a plan view of a flat panel display device according to an embodiment of the present invention;

FIG. 6 is a plan view of a flat panel display device according to another embodiment of the present invention;

FIG. 7 is a plan view of an uncut panel according to another embodiment of the present invention;

FIG. 8 is a plan view of an uncut panel according to still another embodiment of the present invention;

FIG. 9 is a plan view of an uncut panel for manufacturing a plurality of flat panel display devices according to still another embodiment of the present invention;

FIG. 10 is a plan view of a flat panel display device according to yet another embodiment of the present invention;

FIG. 11 is a cross-sectional view of a display array of an organic light emitting device according to an embodiment of the present invention; and

FIG. 12 is a cross-sectional view of another display array of an organic light emitting device according to an embodiment of the present invention.

### DETAILED DESCRIPTION OF EMBODIMENTS

Hereinafter, various features of the present invention will now be described in detail in terms of embodiments and examples with reference to the accompanied drawings.

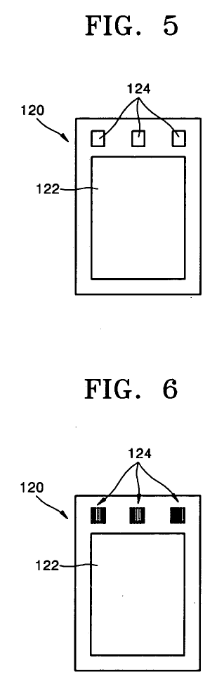

FIG. 4 is a plan view of an uncut original panel 110 for manufacturing a plurality of display arrays according to an embodiment of the present invention. FIG. 5 is a plan view of a flat panel display device cut from the panel 110 according to an embodiment of the present invention.

As depicted in FIG. 4, in one embodiment, a plurality of unit panel sections 120, each forming a single flat panel display device, are simultaneously manufactured on a substrate 112. More specifically, for example, display arrays are deposited on the substrate, and the substrate 112 is cut into multiple pieces of unit panel sections. A partially manufactured flat panel display device after cutting is depicted in FIG. 5.

Referring to FIG. 5, the partially manufactured flat panel display device includes a display array 122 on the substrate, and at least one mark or reference means 124 located outside of the display array 122.

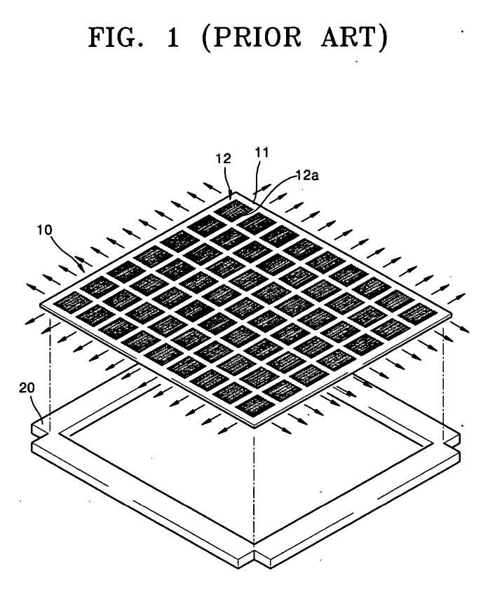

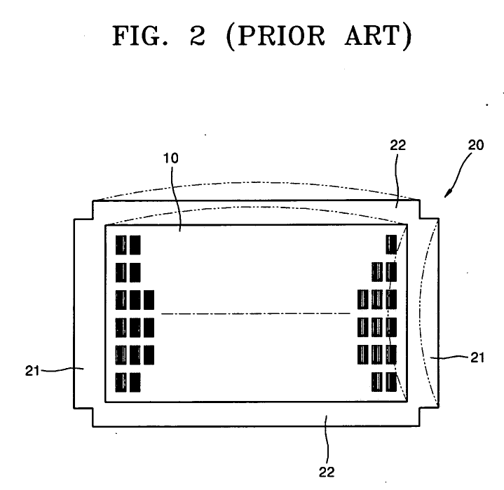

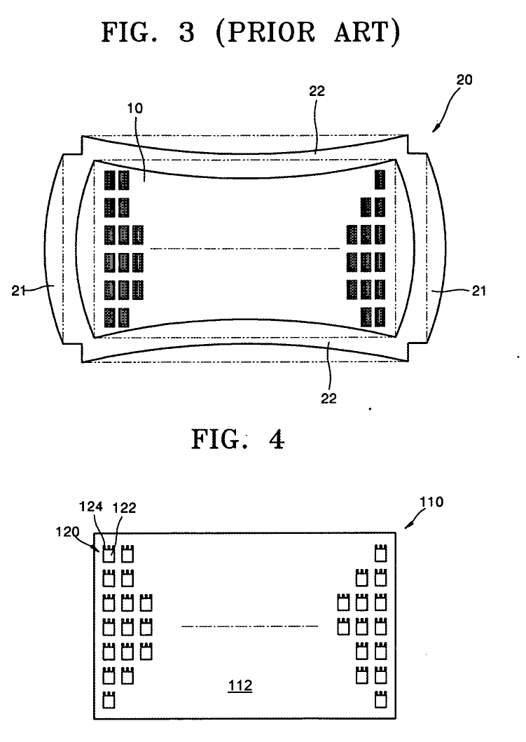

As depicted in FIGS. 1 through 3, the mask 10 includes a plurality of slits or openings, and organic or other materials are selectively deposited on the substrate through the slits or openings. Sometimes, the slits of the mask may not be correctly located where they are supposed to be due to tension applied to the mask 10 to prevent sagging of the mask 10. The slits may be at correct positions, particularly, in the early stage of using the mask 10. But as the mask frame assembly is repeatedly used, the positions of the slits of the mask 10 may be changed due to the deformation of the mask frame. Also the slits themselves may deform as a mask frame assembly is repeatedly used, the mask 10 may produce defective or incorrect display arrays, thereby resulting in heavy loss of time and costs. These losses can be prevented by inspecting the mask frame assembly to determine whether it is deformed or not. The inspection can be achieved using the mark or reference means 124 provided outside of the display array unit 122 as depicted in FIGS. 4 TO 10.

That is, in selectively depositing a material using the mask frame assembly, the deformation of the mask 10, the frame or the slits of the mask 10 can be checked by inspecting the relative location between the slits of the mask 10 and the marks or reference means 124 located outside of the display array 122. If the relative location between the slits of the mask 10 and the marks or reference means 124 is out of a predetermined tolerance limit, a new mask frame assembly replaces with the old one for depositing materials to prevent product failures or defects.

The reference means 124 is one or more printed or deposited structures having a predetermined shape, which is not a part of an operating circuit of the display device. The predetermined shape is substantially unique or distinct from the other structures formed on the substrate 112 such that it can be identified substantially free of confusion with another shape existing in the other structures. In some embodiments, the predetermined shape is one that is not found in the other structures formed on the substrate 112, which are depositions of materials to form circuits and display arrays. In some embodiments, the predetermined shape can be substantially unique or distinct from the other structures by its location, size, isolation from the other structures and/or combination with one or more other structures. Examples of the reference means or its predetermined shape may include one or more shapes including circles, ellipses, triangles, squares, rectangles, pentagons, hexagons, other polygons, stars, a series of dots, a pattern of arranged dots, a series of stripes, parallel stripes, straight lines, curved lines, interconnected lines to form an outline of various shapes, combined shapes of the foregoing, etc. The reference means may include a structure, which is as thin as it can be considered as a two-dimensional structure. The reference means may include a three-dimensional structure.

As noted above, the mark or reference means 124 is formed on over the substrate 112 outside the region where the display array 122 is formed. The term. “mark” 124 used herein encompass the reference means. Further, the mark may also include other structures that do not belong to the reference means as long as a portion or position thereof can be identified and used as a reference point for determining whether a position on the mask 10 is properly distanced from the reference point. The mark 124 may include one or more structures that are a part of operating circuits in the display device. Here, operating circuits refer to circuits, circuit elements or contacts, in which current flows while operating the display device.

In one embodiment, the mark or reference means 124 has a reference point for determining the relative location between the reference point and some of the slits of the mask 10. In embodiments the reference point may be a point or an edge of the mark, a geometric center, a line or point on the mark, although not limited thereto. In embodiments, the determining the relative location may involve measuring a distance between the reference point and a position on the mask 10 and comparing the measured distance with a desired distance between the reference point and the position on the mask 10. In an exemplary process, to measure the distance, the reference point of the mark and one of more openings of the mask are detected or identified. The detection of the reference point of the mark, for example, may be performed using image processing system with a camera. In this example, the image of the mark and surroundings are acquired by the scanning camera and processed to locate the reference point using characteristic information characterizing the reference point of the mark or reference means. In another example, the reference point of the mark may be located by a scanning light sensor unit emitting light and receiving reflected light by the reference point of the mark or reference means, although not limited thereto.

In other embodiments and in the described embodiment, the relative location may be between the reference point and any location or position on the mask 10. Also, in other embodiments, the mark or reference means 124 may have more than one reference point, and the determining relative location may be conducted for one or more reference points.

In one embodiment, to facilitate the measurement of the relative location between the slits of the mask 10 and the marks or reference means 124, an edge of the slits of the mask 10 may be parallel to an edge of the marks 124, although not limited thereto. When an edge of the slits of the mask 10 is parallel to an edge of the marks 124, the marks 124 may have a rectangular shape as depicted in FIGS. 4 and 5. However, the shape of the marks 124 is not limited to the rectangular shape. Also, for the sake of convenience, three marks 124 are shown in FIGS. 4 and 5 in the illustrated embodiment, but more than three marks 124 can be formed. The same is true for other embodiments which will be described later.

In one embodiment, to check the relative location between the slits of the mask 10 and the marks 124, the marks 124 may be opaque. That is, the marks 124 are formed of an opaque material so that the relative location between the slits of the mask 10 and the marks 124 can be checked. Particularly, for example, when the marks 124 are formed of a reflective material, the relative location between the slits of the mask 10 and the marks 124 can further be precisely checked by detecting light reflected from the marks 124 by use of an optical system using a laser. The same is true for other embodiments which will be described later.

Meanwhile, in another embodiment, the flat panel display device can further include a thin film transistor for controlling a signal, such as a scanning signal, applied to the display array unit. Of course, the thin film transistor can be included the inside of the display array unit, as necessary. The thin film transistor includes a source electrode, a drain electrode, and a gate electrode. The reference means or mark 124 for checking the deformation of the mask frame assembly can be included on the same layer with at least one of the source electrode, the drain electrode, and the gate electrode. In this embodiment, particularly, the reference means or mark 124 can be simultaneously formed with at least one of the source electrode, the drain electrode, and the gate electrode using the same material. In this way, the manufacturing process of the flat panel display device having the reference means or mark 124 outside of the display array 122 can be simplified. In this case, the reference means or mark 124 is formed of a conductive material. Alternatively, the reference means or mark 124 can be formed of a non-conductive material. Even if the mark or reference means 124 is formed of a conductive material, it can have various modifications, for example, the mark 124 may be separately formed from each of the electrodes of the thin film transistor, or disposed on a separated layer. The same is true for other embodiments which will be described later.

In another embodiment, the determining relative location between the mark or reference means and the openings of the mask may be accomplished by determining the relative location between the mark or reference means and one or more positions of pixel patterns selectively deposited using the mask.

In one embodiment, the reference means or mark may be removed and remain as a trace thereof after determining the relative location between the mark and the openings of the mask. In another embodiment, the mark or trace may be buried by a subsequent process, for example, deposition thereover. Alternatively, the mark or trace may be exposed.

FIG. 6 is a plan view of a flat panel display device according to another embodiment of the present invention. In the illustrated embodiment, a flat panel display device also includes reference means or marks 124 outside display array 122. As described above, the purpose of the reference means or marks 124 is to check the deformation of the mask frame assembly, that is, to check the location misalignment of the slits of the mask. In one embodiment, to precisely and correctly check the location misalignment of the slits, the marks 124 included in the flat panel display device according to the present embodiment have a plurality of stripes. The deformation of the mask frame assembly can be readily determined using the stripes, when one slit corresponds to plural stripes of the mark 124, or the number of stripes of the mark 124 corresponding to one or multiple slits is changed.

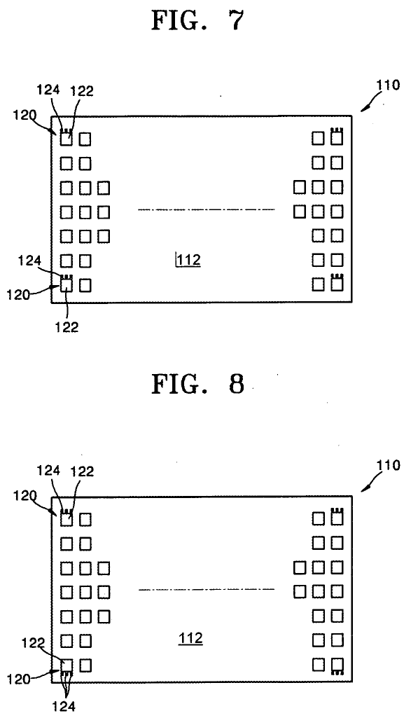

FIG. 7 is a plan view of an uncut panel according to an embodiment of the present invention. The location misalignment of the slits due to the deformation of the mask frame assembly may occur mainly in a peripheral area of the mask. Therefore, as depicted in FIG. 7, in an uncut original panel 110, the reference means or marks 124 may be formed only on the unit panel sections 120 located at corners of the original panel 110. In FIG. 7, the reference means or marks 124 are formed on only one unit panel section 120 located at each corner of the original panel 110, but various modifications are possible. In another embodiment, the marks 124 can be formed on the unit panel sections 120 at each corner along one or more edges of the original panel 110. Also, the reference means and marks 124 may be positioned in various other locations. For example, as depicted in FIG. 8, the reference means or marks 124 can be formed on an edge of the display array 122 facing the edge of the original panel 110.

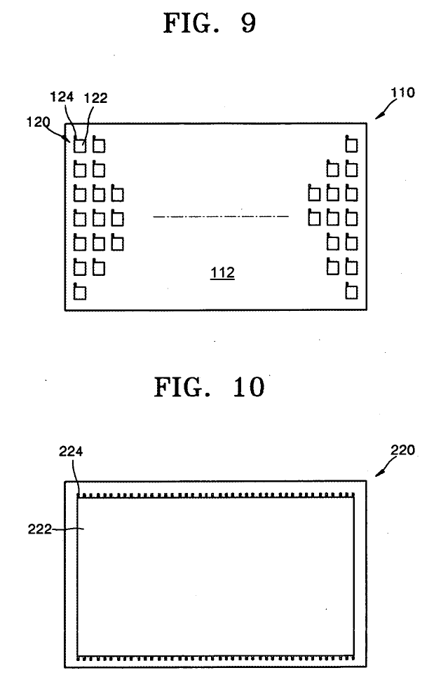

FIG. 9 is a plan view of an uncut panel for simultaneously manufacturing a plurality of flat panel display devices according to still another embodiment of the present invention. The flat panel display devices according to embodiments of the present invention include a plurality of reference means or marks 124 formed on the unit panel sections 120 outside the display array 122. But, as depicted in FIG. 9, in the flat panel display device according to the illustrated embodiment, reference means or a mark 124 is included on the unit panel section 120 outside of the display array 122. Since a flat panel display device may be mounted on a mobile device, such as a mobile phone, the reference means or mark 124 for each unit panel section 120 may be enough to check the location misalignment of the slits due to the deformation of the mask frame assembly during a manufacturing process thereof. Alternatively, the mobile devices can also include a plurality of reference or marks.

FIG. 10 is a plan view of flat panel display device according to yet another embodiment of the present invention. A flat panel display device 220 according to the illustrated embodiment of the present invention is a large size flat panel display device. A plurality of reference means or marks 224 for checking the deformation of the mask frame assembly during a manufacturing process are included. The reference means or marks 224 are formed outside of a display unit 222, and may be formed along at least one edge of the display unit 222. In the example of the flat panel display device 220 depicted in FIG. 10, the marks 224 are formed along two parallel edges of the display unit 222. The use of the marks 224 formed along the edges of the display unit 222 may check the misalignment of the slits on a side of the mask from correct locations while the slits on the opposite side of the mask are correctly aligned in the original locations.

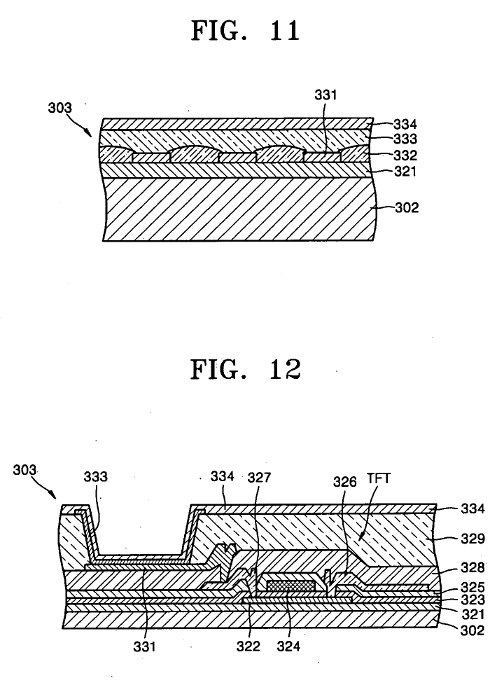

The display unit 222 of the flat panel display device can include various kinds of display elements, such as liquid crystal display elements or organic light emitting display elements. The use of the present invention is advantageous, particularly, in the case of the organic light emitting display elements, since organic films or various electrodes included in the display devices are formed by deposition,. The organic light emitting display element included in the display unit of the organic light emitting display device will now be described with reference to FIGS. 11 and 12.

As described above, a display array and marks (or reference means) formed outside the display array are formed over a substrate 302. The substrate 302 can be formed of a transparent glass material, or can be formed of other materials, such as acryl, polyimide, polycarbonate, polyester, mylar, and other plastic materials.

The present invention can be applied to various organic light emitting display elements, such as a passive matrix type (simple matrix type) organic light emitting display elements or an active matrix type organic light emitting display elements having a thin film transistor.

FIG. 11 is a cross-sectional view illustrating a passive matrix type organic light emitting display element 303. In the illustrated embodiment, a buffer layer 321 formed of SiO₂ is formed on the substrate 302, and a first electrode 331 formed in a predetermined pattern is formed on the buffer layer 321. An intermediate layer 333 that includes at least one light emitting layer and a second electrode 334 are sequentially formed on the first electrode 331. An insulating layer 332 can further be interposed between lines of the first electrode 331, and the second electrode 334 can be formed in a pattern perpendicular to the pattern of the first electrode 331. Even though it is not depicted in FIG. 11, an insulating layer (a separator) formed in a pattern perpendicular to the first electrode 331 for patterning the second electrode 334 can further be included.

The intermediate layer 333 that includes at least a light emitting layer can be formed of a low molecule organic material or a polymer organic material. If the intermediate layer is formed of a low molecule organic material, the intermediate layer can be formed in a single or a composite structure by stacking a Hole Injection Layer (HIL), a Hole Transport Layer (HTL), an Emission Layer (EML), an Electron Transport Layer (ETL), and an Electron Injection Layer (EIL). Organic materials that can be used for forming the intermediate layer includes copper phthalocyanine (CuPc), N,N′-Di(naphthalene-1-yl)-N,N′-diphenyl-benzidine (NPB), and tris-8-hydroxyquinoline aluminum (Alq3), and the present invention is not limited thereto. The low molecule organic layers can be formed by an evaporation method. The low molecule organic material layers can be formed by an evaporation method using the aforementioned mask. The organic material layers can be deposited on correct locations by checking the deformation of the mask frame assembly using the marks outside of the display unit.

When the intermediate layer is formed of a polymer organic material, the intermediate layer generally can have a structure that includes a HTL and an EML. At this time, the HTL can be formed of poly-(2,4)-ethylene-dihydroxy thiophene (PEDOT), and the light emitting layer can be formed of poly-phenylenevinylene (PPV) and Polyfluorene group polymers.

The first electrode 331 functions as an anode electrode and the second electrode 334 functions as a cathode electrode, but the polarity of the first electrode 331 and the second electrode 334 may be reversed. The first electrode 331 can be formed as a transparent electrode or a reflection electrode. When the first electrode 331 is formed as a transparent electrode, the first electrode 331 can be formed of ITO, IZO, ZnO or In2O3, and when the first electrode 331 is formed as a reflection electrode, the first electrode 331 can be formed of ITO, IZO, ZnO or In2O3 on a reflection film after forming the reflection film using Ag, Mg, Al, Pt, Pd, Au, Ni, Nd, Ir, Cr, or a compound of these metals.

The second electrode 334 can also be formed as a transparent electrode or a reflection electrode. When the second electrode 334 is formed as a transparent electrode, after depositing a metal having a low work function, such as Li, Ca, LiF/Ca, LiF/Al, Al, Ag, Mg, or a compound of these metals, on the intermediate layer 333, an auxiliary electrode layer or a bus electrode line formed of a material for forming the transparent electrode, such as ITO, IZO, ZnO or In2O3, can be formed on the intermediate layer 333. When the second electrode 334 is a reflection electrode, the second electrode 334 is formed by entirely depositing Li, Ca, LiF/Ca, LiF/Al, Al, Ag, Mg, or a compound of these metals.

FIG. 12 is a cross-sectional view of another example of an active type organic light emitting display element 303. Referring to FIG. 12, each sub-pixel includes at least one thin film transistor. The thin film transistor according to the present invention is not limited to the structure depicted in FIG. 12, that is, any number of transistors can be included and various modifications of structures are possible. The active type organic light emitting device will now be described briefly with reference to FIG. 12.

As depicted in FIG. 12, in the illustrated embodiment, the buffer layer 321 formed of SiO₂ is formed on the glass substrate 302, and the thin film transistor is formed on the buffer layer 321.

The thin film transistor includes a semiconductor layer 322 formed on the buffer layer 321, a gate insulating film 323 formed on the semiconductor layer 322, and a gate electrode 324 on the gate insulating film 323. The gate electrode 324 is connected to a gate line that applies signals to the thin film transistor. A region where the gate electrode 324 is formed corresponds to a channel region of the semiconductor layer 322. An inter-insulating layer 325 is formed on the gate electrode 324, and a source electrode 326 and a drain electrode 327 are respectively formed to connect to a source region and a drain region through contact holes.

A passivation film 328 formed of SiO2 is formed on the source electrode 326 and the drain electrode 327, and a pixel define film 329 formed of acryl or polyimide is formed on the passivation film 328. The passivation film 328 may function as a protection film for protecting the thin film transistor, and or as a planarizing film that planarizes the upper surface of the thin film transistor.

At least one capacitor (not shown) is connected to the thin film transistor. The present invention is not limited the circuit that includes the thin film transistor depicted in FIG. 12, but various modifications are possible.

Meanwhile, an organic light emitting display element is connected to the drain electrode 327. The first electrode 331 of the organic light emitting display element is formed on the passivation film 328, the insulating pixel define film 329 is formed on the passivation film 328, and the intermediate layer 333 that includes at least one light emitting layer is formed in a predetermined opening included in the pixel define film 329. For convenience of explanation, in FIG. 12, the intermediate layer 333 is patterned to correspond only to each of the sub-pixels. However, this is only an example of the structure of the sub-pixel, and intermediate layers can be modified in various ways. For example, adjacent sub-pixels can be formed in one body. When the intermediate layer 333 has multiple layers, a portion of the multiple layers can be formed in one body with adjacent sub-pixels.

The material for forming the first electrode 331, the second electrode 334, the intermediate layer 333 interposed between the first electrode 331 and the second electrode 334, and intermediate layers (not shown) disposed on and under the intermediate layer 333 can be the same material like the material for forming the passive type organic light emitting device.

The organic light emitting display element formed on the substrate 302 is sealed by a facing member (not shown). The facing member can be formed of glass or a plastic material like the substrate 302, or can be formed in a metal cap.

In an organic light emitting display device that includes organic light emitting display elements having the above structure, product failures during a manufacturing process can be prevented by checking the deformation of mask frame assemblies prior to depositing organic films using marks formed on unit panel sections outside of a display unit, thereby reducing manufacturing costs.

The aforementioned embodiments of the present invention are described with respect to organic light emitting display elements, but the present invention is not limited thereto. That is, the present invention can be applied to any display device that is manufactured by selective deposition.

The flat panel display device according to the present invention has the following advantages. First, the deformation of the mask frame assembly can be checked prior to depositing organic films on each substrate or depositing a set of substrates by checking the location of slits using marks formed outside of the display unit. Second, the product failure during a manufacturing process can be prevented by detecting the deformation of the mask or reference means frame assembly prior to depositing organic films.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A display device, comprising:
a substrate comprising a first area and a second area outside the first area;
a display array formed over the first area of the substrate, the array comprising a plurality of pixels, the plurality of pixels comprising a layer of a deposited material; and
reference means or a trace of such means for referencing in determining whether a deformation of a deposition mask for depositing the layer is within predetermined deformation tolerance limit, the means or trace being formed over the second area of the substrate.

2. The device of claim 1, wherein the reference means provides a reference point to determine whether a distance between a position on the deposition mask and the reference point is within a predetermine distance tolerance limit.

3. The device of claim 1, wherein the means or the trace is buried under a structure.

4. The device of claim 1, wherein the means or the trace is exposed.

5. The device of claim 1, wherein the means have a rectangular shape.

6. The device of claim 1, wherein the means comprises a plurality of substantially parallel stripes.

7. The device of claim 1, wherein the display array comprises a structure made of an electrically conductive material, and wherein the means comprises the same electrically conductive material.

8. The flat panel display device of claim 7, wherein the structure is selected from the group consisting of a source electrode, a drain electrode and a gate electrode of a transistor, and wherein the reference means is located on the same layer as the structure.

9. The device of claim 1, wherein wherein the means is arranged along at least one of edges of the first area.

10. The device of claim 9, wherein two or more means are arranged along at lease two of the edges of the first area.

11. The device of claim 1, wherein the plurality of pixels comprises an organic light emitting diode.

12. A method for making a display device, the method comprising:
providing a substrate comprising at least one mark on a predetermined position;
placing a deposition mask over the substrate, the deposition mask comprising a plurality of openings, through which a plurality of portions of the substrate are exposed; and
determining whether deformation of the deposition mask is within a predetermined deformation tolerance limit using the at least one mark.

13. The method of claim 12, wherein determining comprises:
determining whether a position on the deposition mask relative to the at least one mark is within at least one predetermine tolerance limit.

14. The method of claim 12, wherein determining comprises:
measuring a distance between the at least one mark and a position on the mask; and
comparing the measured distance with a predetermined value.

15. The method of claim 12, further comprising replacing the deposition mask with another deposition mask, if the deformation of the deposition mask is out of the predetermined deformation tolerance limit.

16. The method of claim 12, wherein providing the substrate comprises forming the at least one mark on the substrate, and wherein the at least one mark is formed simultaneously with one or more components of the display device formed on the substrate.

17. A flat panel display device produced by the method of claim 12.
